(19) United States
(12) Patent Application Publication
(10) Pub. No.: US 2005/0178328 A1
(43) Pub. Date: Aug. 18, 2005

(54) Film forming method and film forming apparatus

(75) Inventors: Hiroki Imamura, Ibusuki-gun (JP); Tomoya Tanaka, Amata-gun (JP); Yoshinori Takamori, Soraku-gun (JP)

Correspondence Address: STEVENS DAVIS MILLER & MOSHER, LLP, 1615 L STREET, NW, SUITE 850, WASHINGTON, DC, 20036, US

(73) Assignee: MATSUSHITA ELECTRIC INDUSTRIAL CO., LTD., Osaka (JP)

(21) Appl. No.: 11/047,655

(22) Filed: Feb. 2, 2005

(30) Foreign Application Priority Data
Feb. 17, 2004 (JP) 2004-039423

(51) Int. Cl. C23C 16/00

(52) U.S. Cl. 118/719; 427/250

(57) ABSTRACT

The object of the present invention is provide a film forming method and a film forming apparatus for suppressing mixing of an organic type foreign material into a film forming chamber when forming a film, thereby reducing a defect density after a film formation. In order to achieve the object, the film forming apparatus comprises a load lock for placing a cassette for holding a wafer, a film forming chamber for forming a thin film on the wafer, and an arm for conveying the wafer from the load lock to the film forming chamber, wherein a mass spectrograph for measuring a partial pressure of an organic substance under an atmosphere in the load lock is placed in the load lock. In the film forming method, an atmosphere in the load lock in which a cassette holding the wafer is placed is firstly exhausted. In this exhaust, the exhaust is performed until a partial pressure of the organic substance under the atmosphere in the load lock reaches 7.5×10⁻⁵ mTorr or less. The wafer is conveyed to a film forming chamber for a desired thin film to be formed.

### BACKGROUND OF THE INVENTION

1. Field of the Invention

The present invention relates to a film forming method and a film forming apparatus of forming a thin film used for a metal film and an insulation film of a semiconductor device.

2. Description of the Prior Art

In recent years, with high integration, advanced features and improvement in speed of a semiconductor integrated circuit device, microfabrication and reduction in film thickness of an interconnection in a semiconductor are remarkably improved. Therefore, there are disclosed some approaches for reduction in interconnection resistance, improvement in stress migration and electromigration, or the like (for example, refer to Japanese Laid-Open Patent Application Publication No. 2000-77359). Meanwhile, in a thin film forming technology, there is a problem that a film formation defect is generated owing to an organic contamination, so that reduction in said organic contamination is an urgent necessity.

Hereafter, referring to the drawings, description will be made of an example of a film forming method and a film forming apparatus in the prior art.

FIG. 5 is a view showing an outline of the film forming method and a film forming chamber in the prior art. FIG. 6 is a view showing an outline of the whole film forming apparatus.

In FIG. 5, an aluminum alloy target 52 is attached in an upper part inside a magnetron sputtering chamber 51. In order to form a metal thin film for interconnection, a wafer 54 which is a semiconductor substrate is placed inside the magnetron sputtering chamber 51 so as to be opposed to the aluminum alloy target 52.

In addition, a flange 55 connects the magnetron sputtering chamber 51 to an RGA device 53 which is a residual gas analysis apparatus. This RGA device 53 is used for evaluating impurities and pressures of impurity gases inside the magnetron sputtering chamber 51.

Next, in FIG. 6, a PEEK cassette 61 which is formed of a PEEK material holds the wafers 54 of a pre-sputtering process and a post-sputtering process. In order to convey the wafer 54 from the air to the magnetron sputtering chamber 51 which is kept at high vacuum, evacuation of a load lock 62 is performed by a vacuum pump 64. Incidentally, the PEEK (polyetheretherketone) is a resin having a high strength property in addition to a superior chemical resistance and heat resistance. Although a Teflon® cassette has originally been used, there has been a problem of an electrostatic property, so that a PP (polypropylene) cassette has been used. However, the PP has a problem in a heat resistance and the PEEK cassette has now been used.

Description will be made of a film forming method and a film forming apparatus configured as described above.

First, the PEEK cassette 61 is carried into the load lock 62, evacuation is performed by the vacuum pump 64 until the load lock 62 reaches a high vacuum state, and the wafer 54 is conveyed within the magnetron sputtering chamber 51. Next, when a film which is composed of an aluminum alloy is formed on the wafer 54 by a sputtering method, the film which is composed of the aluminum alloy is formed with controlling a partial pressure using the RGA device 53, so that a ratio of the partial pressure of nitrogen and oxygen which are contained in an argon gas under a sputtering film formation to a whole sputtering gas may become approximately 51 ppm or less, preferably approximately 11 ppm or less, respectively. Alternatively, the film is formed such that nitrogen, oxygen, and hydrogen contained in the film which is composed of the aluminum alloy on the wafer 54 may be controlled to be approximately 0.003 atom % or less, preferably approximately 0.01 atom % or less, most preferably approximately 0.006 atom % to the whole film, respectively.

In the conventional film forming method and film forming apparatus, when an organic component is carried into the load lock, an organic type foreign material adheres on the wafer before the film formation or the thin film formed after the film formation processing in a film formation process, and said thin film and said organic type foreign substance react, so that the thin film changes into a material different from a desired film. Consequently, a desired thin film removal cannot be performed in an etching process or a cleaning process which will be carried out after said film formation process, so that there has arisen a problem that when said thin film has been a metal thin film, an interconnection fault or a gate formation fault has been generated, and when said thin film has been an insulation film, an insulation fault between interconnections has been generated, resulting in high defect density.

### SUMMARY OF THE INVENTION

The object of the present invention is to provide a film forming method and a film forming apparatus which can reduce a contamination owing to an organic type foreign material carried from an outside of a film forming chamber, and an organic type foreign material generated from a cassette used for semiconductor substrate conveyance.

In order to achieve the object described above, according to a film forming method of a first aspect of the present invention, it includes the steps of (a) exhausting an atmosphere in a load lock in which a cassette for holding a wafer is placed, (b) conveying the wafer into a film forming chamber after the step (a), and (c) forming a thin film on the wafer after the step (b), wherein at the step (a), exhaust is performed until a partial pressure of an organic substance under an atmosphere in the load lock reaches a partial pressure of the organic substance when exhaust is performed in the state where a cassette is not contained in the load lock.

According to this configuration, at the step (a), the exhaust is performed until the partial pressure of the organic substance under the atmosphere in the load lock reaches the partial pressure of the organic substance when the exhaust is performed in the state where the cassette is not contained in the load lock, so that it is possible to remove the organic type foreign material in the load lock, thereby making it possible to prevent the organic type foreign material from being introduced into the film forming chamber. Therefore, since the wafer surface is always kept in a state where it is not exposed to the organic type foreign material, a desired thin film can be formed, thereby making it possible to reduce a defect density.

According to a film forming method of a second aspect of the present invention, in the film forming method of the first aspect of the present invention, the partial pressure of the organic substance when the exhaust is performed in the state where the cassette is not contained is 7.5×10⁻⁵ mTorr or less.

According to a film forming method of a third aspect of the present invention, in the film forming method of the first or the second aspect of the present invention, a composition of the organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

According to a film forming apparatus of a fourth aspect of the present invention, it comprises a load lock for placing a cassette for holding a wafer, a film forming chamber for forming a thin film on the wafer, and an arm for conveying the wafer from the load lock to the film forming chamber, wherein a mass spectrograph for measuring a partial pressure of an organic substance under an atmosphere in the load lock is placed in the load lock.

According to this configuration, it is possible to prevent an organic type foreign material from being introduced into the film forming chamber, so that an effect similar to that of the first aspect of the present invention can be obtained.

According to a film forming apparatus of a fifth aspect of the present invention, in the film forming apparatus of the fourth aspect of the present invention, wherein the load lock is designed to be able to perform evacuation until the partial pressure of the organic substance measured by the mass spectrograph reaches 7.5×10⁻⁵ mTorr or less.

According to a film forming apparatus of a sixth aspect of the present invention, in the film forming apparatus of the fourth or the fifth aspect of the present invention, wherein the cassette is composed of a metallic material.

According to this configuration, generation of the organic type foreign material can be suppressed.

According to a film forming apparatus of a seventh aspect of the present invention, in the film forming apparatus of the fourth, fifth or sixth aspect of the present invention, a composition of the organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

### BRIEF DESCRIPTION OF THE DRAWINGS

FIG. 1 is a view showing a rough outline of a sputtering apparatus in an embodiment of the present invention;

FIG. 2 is a graph showing a time change of a partial pressure of an organic component in a load lock;

FIG. 3 is a graph showing the amount of organic type particle in each cassette;

FIG. 4 is a graph showing a defect density in each cassette;

FIG. 5 is a view showing a cross section of a film forming chamber in the prior art; and

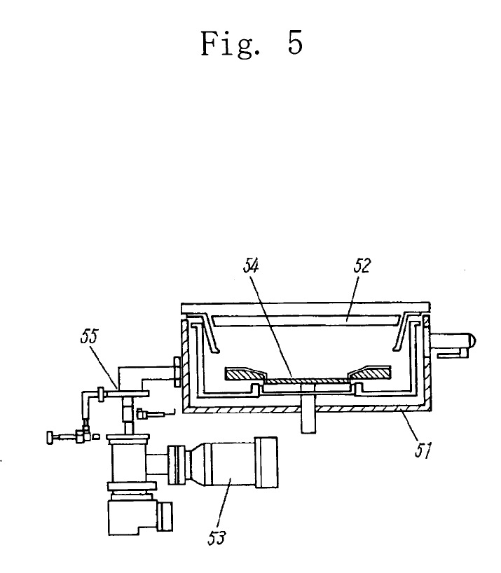

FIG. 6 is a view showing an outline of a film forming apparatus in the prior art.

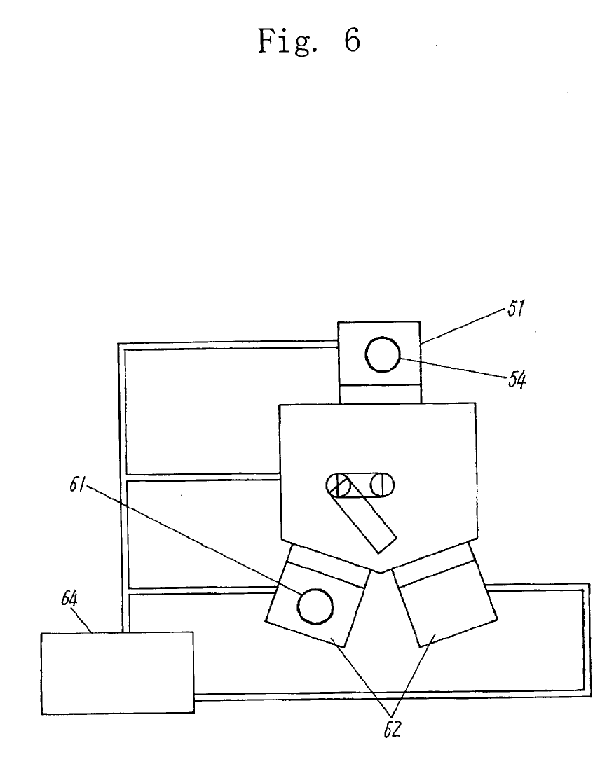

### DETAILED DESCRIPTION OF THE PREFERRED EMBODIMENTS

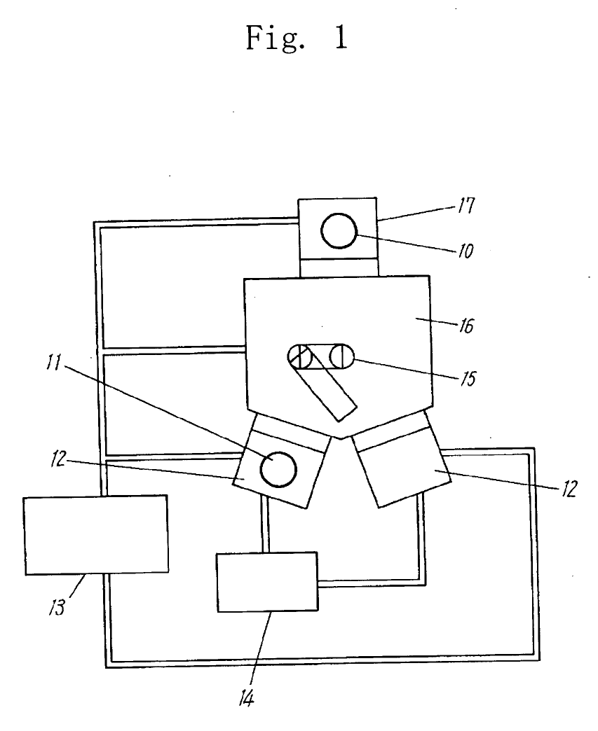

Hereinafter, description will be made of embodiments of the present invention based on FIG. 1 through FIG. 4. FIG. 1 shows a film forming apparatus of the embodiment of the present invention, and is a schematic diagram of a cobalt sputtering apparatus for performing a film deposition by means of sputtering under an existence of various impurity gases.

As shown in FIG. 1, it comprises a load lock 12 for placing a cassette 11 for holding a wafer 10, a film forming chamber 17 for forming a thin film on the wafer 10, and an arm 15 for conveying the wafer 10 from the load lock 12 to the film forming chamber 17. In addition, a Q-MASS (mass spectrograph) 14 for measuring a partial pressure of an organic substance in an atmosphere in the load lock 12 is placed in the load lock 12.

The wafer 10 used in this embodiment is a disc-like silicon substrate with a diameter of eight inches. The metal cassette 11 can contain the wafers 10 of about 25. The load lock 12 contains the metal cassette 11 conveyed from a conveyance pod, and can be evacuated to a desired pressure. The vacuum pump 13 evacuates the load lock 12, a conveyance chamber 16, and a wafer film forming chamber 17. The Q-MASS 14 is connected to the load lock 12, performs an organic component analysis for the gas in the load lock 12, and controls a wafer conveyance. The robot arm 15 is in the conveyance chamber 16, holds the wafer 10, and conveys the wafer to a desired unit. The conveyance chamber 16 conveys the wafer 10 by means of using the robot arm 15 between the load lock 12 and the film forming chamber 17. The film forming chamber 17 deposits a desired thin film on the wafer 10. The load lock 12 can be exposed to the atmosphere, and the wafer cassette 11 can be carried thereinto from an external apparatus. Moreover, a shutter which can be opened and closed provides a vacuum isolation among the load lock 12, the conveyance chamber 16, and the film forming chamber 17.

Incidentally, this figure only shows the outline of the apparatus, and the number of vacuum pumps, the number of chambers, the pipe arrangement path, and the like are simplified and described.

The present inventors have found out that a defect caused by a formation fault of a cobalt film or its alloy film has been dependent on an organic type foreign material generated within the load lock as a result of various experiments. The present invention has been achieved based on this knowledge.

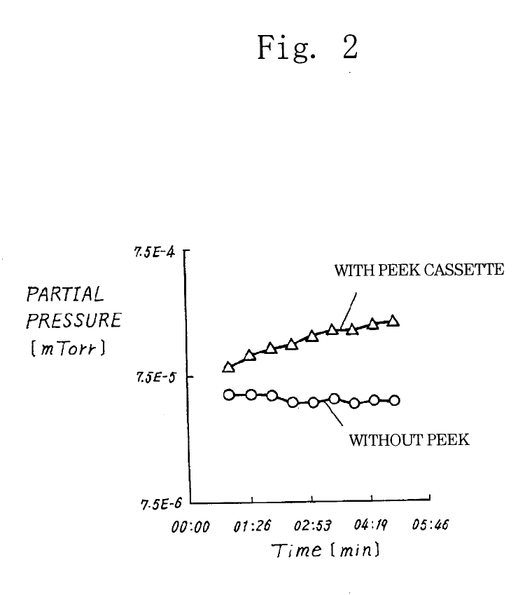

As a first experiment, using a semiconductor manufacturing apparatus shown in FIG. 1, the organic type foreign material generated from a PEEK cassette which is generally used as a resin-made cassette is measured. First, the PEEK cassette which has been conventionally used is carried into the load lock 12, it is evacuated by the vacuum pump 13, and the partial pressure of the organic substance (AMU 50-150) for 5 minutes is measured using the Q-MASS 14 in a condition where evacuation by said vacuum pump 13 is stopped. Next, the cassette is not put into the load lock 12, it is evacuated by the vacuum pump 13, and the partial pressure of the organic substance (AMU 50-150) for 5 minutes is measured using the Q-MASS 14 in a condition where evacuation by said vacuum pump 13 is stopped. These results are shown in FIG. 2. According to FIG. 2, the partial pressure of the organic substance is increased in the condition where said PEEK cassette is contained in said load lock 12 as compared with the condition where the PEEK cassette is not contained in said load lock 12. That is, it turns out that outgassing of the organic substance of at least 7.5×10⁻⁵ mTorr or more is generated from the PEEK cassette.

According to the result described above, the embodiment of the present invention has a form that when evacuation inside the load lock of this apparatus is performed, if the partial pressure of the organic substance generated from the cassette is 7.5×10⁻⁵ mTorr or less, the wafer can be conveyed.

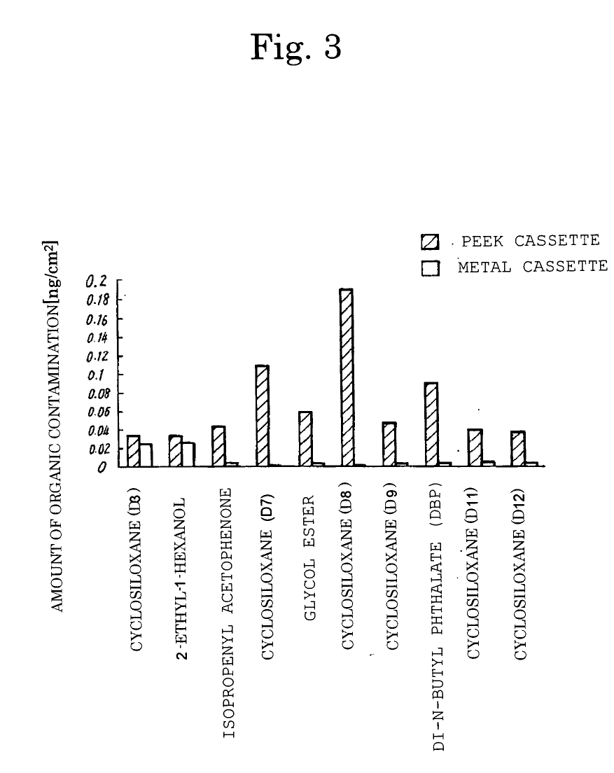

As a second experiment, using the semiconductor manufacturing apparatus shown in FIG. 1, the amount of the organic substance generated from the PEEK cassette and that from the metal cassette 11 have been measured. After carrying the PEEK cassette into which the first wafer 10 has been inserted into the load lock 12, evacuating it by the vacuum pump 13, and then returning the load lock 12 to the atmospheric pressure, the amount of the surface organic substance of the first wafer 10 has been measured using an IN-SITU mass spectrograph. Next, after carrying the metal cassette 11 into which the second wafer 10 has been inserted into the load lock 12, evacuating it by the vacuum pump 13, and then returning the load lock 12 to the atmospheric pressure, the amount of the organic substance which adhere to the surface of the second wafer 10 has been measured using the IN-SITU mass spectrograph. The measurement results of the first wafer 10 and the second wafer 10 measured using the IN-SITU mass spectrograph are shown in FIG. 3.

According to FIG. 3, it turns out that the organic substances, such as an annular siloxane (D3, D7, D8, D9, D11, D12), a 2-ethyl-1-hexanol, an isopropenyl acetophenone, a glycol ester, a Di-n-butyl phthalate (DBP) or the like are outgassed from the surface of the PEEK cassette, and adhere to the surface of the first wafer 10. On the other hand, as for the adhesion to the second wafer 10 from the metal cassette 11, it turns out that the cyclosiloxane (D3) and the 2-ethyl-1-hexanol are suppressed to be 0.04 ng/cm² or less, respectively, and the cyclosiloxane (D7, D8, D9, D11, D12), the isopropenyl acetophenone, the glycol ester, and the Di-n-butyl phthalate (DBP) are suppressed to be 0.01 ng/cm² or less, respectively.

Comparing the total amounts of the organic substances between two cases, when the PEEK cassette is used, the amount of the organic substances of about 1.30 ng/cm² is generated whereas when the metal cassette 11 is used, the amount of the organic substances is about 0.07 ng/cm², so that it turns out that the amount of the organic substances which adhere to the second wafer 10 when using the metal cassette 11 is significantly reduced as compared to that when using the PEEK cassette.

A defect density of the transistor when using the PEEK cassette has been compared with that when using the metal cassette 11 under the same conditions as that of the above second experiment. After a third wafer 10 in which a transistor gate with a gate length of about 100 nm is formed is firstly inserted into the PEEK cassette, and is carried into the load lock 12, evacuation is performed by the vacuum pump 13. The third wafer 10 is then conveyed into the film forming chamber 17 through the conveyance chamber 16. A cobalt film is deposited on a surface of the third wafer 10 within the film forming chamber 17 by means of sputtering in an argon gas atmosphere. The third wafer 10 is then returned to the PEEK cassette in the load lock 12 via the conveyance chamber 16. A transistor and an interconnection are then formed in the third wafer 10 and the defect density of the transistor is measured by measurement equipment.

After a fourth wafer 10 in which a transistor gate with the same gate length of about 100 nm as that of the third wafer 10 is formed is then inserted into the metal cassette 11, and carried into the load lock 12, evacuation is performed by the vacuum pump 13. The fourth wafer 10 is then conveyed into the film forming chamber 17 through the conveyance chamber 16. A cobalt film is deposited on a surface of the fourth wafer 10 within the film forming chamber 17 by means of sputtering in the argon gas atmosphere under the same conditions as that of the third wafer 10. The fourth wafer 10 is then returned to the metal cassette 11 in the load lock 12 via the conveyance chamber 16. A transistor and an interconnection are then formed in the fourth wafer 10 under the same condition as that of the third wafer 10, and a defect density of the transistor is measured by means of the measurement equipment.

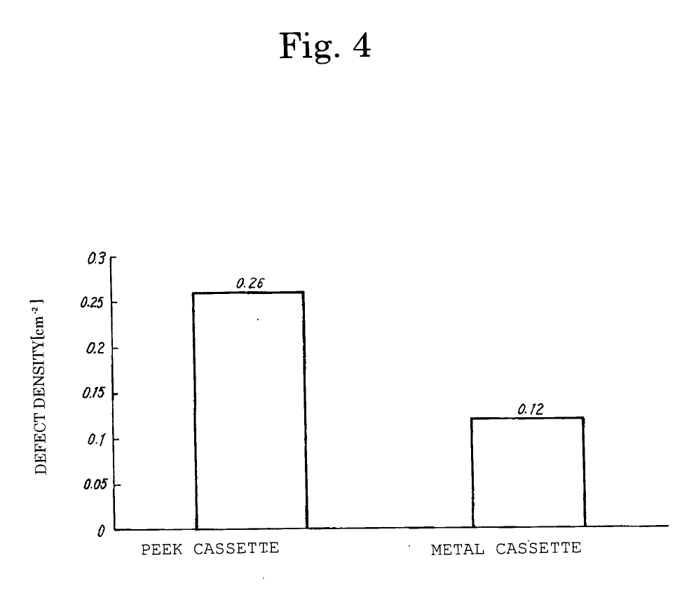

The defect density measurement results of the third wafer 10 and the fourth wafer 10 are shown in FIG. 4. As can be seen from this graph, in the case of the PEEK cassette, the defect density is 0.26 cm⁻², whereas in the case of the metal cassette 11, the defect density is 0.12 cm⁻², resulting in a reduction in defect density by about 53.8%. This result shows that the defect of the transistor is generated since the organic type foreign material has reacted with the cobalt film on the wafer surface to cause the film formation fault, and also shows that the defect density will be reduced when the desired thin film is formed owing to a reduction in the organic substance particle.

As mentioned above, if the load lock is evacuated using the metal cassette, since the organic substance contamination will be reduced to 0.07 ng/cm² or less, it is possible to manufacture a semiconductor device with lower defect density. As a result of that, that the amount of the organic type foreign material adhering to the wafer surface is to be 0.07 ng/cm² or less is the best embodiment to implement the present invention.

According to the above experimental result, the best form of the film forming method and the film forming apparatus which are used in the embodiment of the present invention is a form where the pump 13 capable of evacuation is placed in the load lock 12 of the apparatus, and the metal cassette 11 is used as the cassette for carrying the wafer 10 into the load lock 12. Further, the best form thereof is a form where the wafer 10 is controlled not to be conveyed into the film forming chamber 17 until the partial pressure of the organic substance at the time of evacuating the load lock 12 has reached 7.5×10⁻⁵ mTorr or less, and the amount of the organic type foreign material adhering to the wafer surface is reduced to 0.07 ng/cm² or less.

Hereinafter, description will be specifically made of the film forming method according to the embodiment of the present invention. In FIG. 1, the metal cassette 11 containing the wafer 10 is carried into the load lock 12, and the inside of said load lock 12 is evacuated into a high vacuum state by the vacuum pump 13. When said load lock 12 will be in the high vacuum state, the partial pressure of the gas in said load lock 12 is measured by the Q-MASS 14. The wafer 10 is conveyed to the conveyance chamber 16 by the robot arm 15 based on the measurement result of said Q-MASS 14. The wafer 10 conveyed to the conveyance chamber 16 by the robot arm 15 is conveyed to the film forming chamber 17 for the desired thin film to be deposited.

In this embodiment, after evacuating the inside of the load lock 12 of the apparatus into a vacuum state, the partial pressure within said load lock 12 is measured by the Q-MASS 14, and the atmosphere in the load lock 12 is exhausted until the partial pressure of AMU corresponding to the organic type contamination has reached 7.5×10⁻⁵ mTorr or less, so that the wafer 10 is controlled not to be conveyed into the film forming chamber 17.

Incidentally, in order to prevent the outgasses resulting in the organic type contamination generated from the cassette for wafer conveyance when the pressure in the load lock the apparatus is evacuated, the metal cassette is used, but the material is not limited to that as far as it is formed of a material in which the amount of the organic substance contamination adhering to the wafer surface is 0.07 ng/cm² or less.

1. A film forming method, including the steps of:
(a) exhausting an atmosphere in a load lock in which a cassette for holding a wafer is placed;
(b) conveying said wafer into a film forming chamber after said step (a); and
(c) forming a thin film on said wafer after said step (b)
wherein at said step (a), exhaust is performed until a partial pressure of an organic substance under an atmosphere in the load lock reaches a partial pressure of the organic substance when exhaust is performed in a state where said cassette is not contained in said load lock.

2. The film forming method according to claim 1, wherein the partial pressure of the organic substance when the exhaust is performed in the state where said cassette is not contained is 7.5×10⁻⁵ mTorr or less.

3. The film forming method according to claim 1, wherein a composition of said organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

4. A film forming apparatus, comprising:
a load lock for placing a cassette for holding a wafer;
a film forming chamber for forming a thin film on said wafer; and
an arm for conveying said wafer from said load lock to said film forming chamber,
wherein a mass spectrograph for measuring a partial pressure of an organic substance under an atmosphere in said load lock is placed in said load lock.

5. The film forming apparatus according to claim 4, wherein said load lock is designed to be able to perform evacuation until the partial pressure of the organic substance measured by said mass spectrograph reaches 7.5×10⁻⁵ mTorr or less.

6. The film forming apparatus according to claim 4, wherein said cassette is composed of a metallic material.

7. The film forming apparatus according to claim 3, wherein a composition of said organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

8. The film forming method according to claim 2, wherein a composition of said organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

9. The film forming apparatus according to claim 5, wherein said cassette is composed of a metallic material.

10. The film forming apparatus according to claim 8, wherein a composition of said organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

11. The film forming apparatus according to claim 4, wherein a composition of said organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).

12. The film forming apparatus according to claim 5, wherein a composition of said organic substance includes at least one of an annular siloxane (D3, D7, D8, D9, D11, D12), a 2-ethyl-1-hexanol, an isopropenyl acetophenone, a glycol ester, and a Di-n-butyl phthalate (DBP).
